(19) United States
(12) Patent Application Publication
(10) Pub. No.: US 2016/0131688 A1
(43) Pub. Date: May 12, 2016

(54) DETERMINING AN ORIENTATION OF A METERING DEVICE IN AN ENERGY GENERATION SYSTEM

(71) Applicant: SolarCity Corporation, San Mateo, CA (US)

(72) Inventor: Eric Daniel Carlson, San Mateo, CA (US)

(73) Assignee: SolarCity Corporation, San Mateo, CA (US)

(21) Appl. No.: 14/933,813

(22) Filed: Nov. 5, 2015

Related U.S. Application Data
(60) Provisional application No. 62/078,335, filed on Nov. 11, 2014.

(51) Int. Cl. G01R 22/10

(52) U.S. Cl. CPC G01R 22/10

(57) ABSTRACT

A method comprising requesting power measurement data from a power meter during a predetermined time period, receiving the power measurement data, associating a negative coefficient with the power measurement data if the power measurement is less than zero, associating a positive coefficient with the power measurement data if the power measurement is equal to or greater than zero, and calculating a power measurement for the power generation site based, in part, on the associated coefficients. The power meter can be configured to measure power usage from the EG site including power provided by an electrical utility grid and an EG system at the EG site. The power measurement data may include a first power measurement corresponding to a first phase of power and a second power measurement corresponding to a second phase of power.

### CROSS REFERENCE TO RELATED APPLICATIONS

This claims the benefit of U.S. Provisional Application No. 62/078,335, filed Nov. 11, 2014, which is hereby incorporated by reference in its entirety for all purposes.

### BACKGROUND

In recent years, climate change concerns, federal/state initiatives, and other factors have driven a rapid rise in the installation of renewable energy generation (EG) systems (i.e., systems that generate energy using renewable resources such as solar, wind, hydropower, etc.) at residential, commercial, and industrial sites. Solar photovoltaic (PV) systems, in particular, are increasingly popular as PV installations become more effective and more affordable to the general public.

An EG system is typically combined with an existing electrical system coupled to an electric utility grid and provisioned by, for example, a local power company. The EG system may be coupled to a main panel (i.e., main line) and can generate additional power that can be available to all loads at a site. Additionally, the EG system can be “grid connected” such that any over generation (e.g., EG generation that is greater than an immediate load requirement) can be stored in a local storage device or fed back to the utility through the main panel. This may result in a credit on the site owner's electricity bill and/or allow the surplus energy to be conveyed to others connected to the utility grid.

Many contemporary EG systems may be monitored and/or controlled remotely by one or more servers, mobile devices, or other computing systems. In order to determine how much energy is being consumed and generated at a site, a monitoring device such as a load meter is coupled to the main panel at an installation site. Load meters typically monitor the energy consumption and EG production at predetermined intervals, in real-time, on an as-need basis, or a combination thereof. Power measurement data generated by the load meter may be communicated to a controlling system through any suitable medium (e.g., hard-wired, wireless communication, etc.).

The accuracy of the power measurement data can depend, in part, on the quality of the physical installation of the load meters. During some EG system installations, technicians may inadvertently install load meters backwards, resulting in incorrect measurements. Sometimes installation errors are not discovered until after the EG system installation is complete. In these cases, a technician typically has to return to the installation site to correct the error, which can be expensive and time consuming. These types of installation errors, when scaled in proportion with hundreds or thousands of system installations per day, can result in substantial inefficiencies and waste, as well as delayed and reduced system performance.

### SUMMARY

Systems and methods of the invention can determine a load meter installation orientation in a grid-connected EG system (e.g., a photo-voltaic-based energy generation system) at a site to accurately determine a net load. An improperly installed load meter (e.g., installed backwards) will report power measurements that are inverted (incorrect polarity) rendering net power readings that include utility and EG system energy contributions to be incorrect. In some embodiments, after a load meter is installed, a server (e.g., a gateway computer) may request power measurement data from a power meter at the site during a predetermined time period. The predetermined time period may occur, e.g., between the hours of 12 midnight and 2 A.M., so that any power flow into the grid-connected EG system can be assured to be provisioned by the utility grid and not from the PV panels at the site because little to no sunlight is converted into electricity during that period of time. The server then receives the power measurement data from the load meter and, if necessary, associates a correction coefficient to any further data received from that power meter. Other predetermined time periods are possible and are further discussed below at least with respect to FIG. 11.

In some cases, a negative coefficient (e.g., (−1)) can be associated with the power measurement data if the power measurement is less than zero. That would indicate that the EG system is pushing power back into the grid (back to the utility). Because the PV panels are not generating significant power during this time, it can be assumed that the power meter was installed backwards and associating a negative coefficient with the power measurement will correct the reading (i.e., identify power being received from the utility) in future measurements. Similarly, a positive coefficient can be associated with the power measurement data if the power measurement is equal to or greater than zero. This would indicate power coming in from the grid, which would be expected during the predetermined time period. Because no change is required, this step may be optional. Finally, a power measurement can be calculated for the power generation site based, in part, on the associated coefficients. In other words, the server factors in the associated coefficients (if applicable) to subsequent power measurement data. This can be advantageous as subsequent power readings are then corrected and there is no need to have a service technician return to the installation site to correct the orientation of the power meter.

In some implementations, the power meter measures the power being delivered to the load at the electrical panel and transmits the collected data to a local site gateway via wired or wireless communication methods. This can provide users with remote access and smart metering capabilities. Certain embodiments of the present invention provide systems and methods to remotely determine whether the sensing hardware is correctly installed, and if necessary, manipulate incoming data to ensure a correct polarity regardless of the physical configuration of the measuring hardware.

Embodiments of the invention relate to measuring the power flow of PV system using current transducers on each phase of a 1, 2- or 3-phase power line. By measuring the electrical current during periods of low PV power generation (e.g., between midnight and 2 AM), one can be reasonably assured that the utility grid is primarily powering the site load and that power measurements with a positive polarity are expected during these periods. Thus, power measurements that have a negative polarity during periods of low PV power generation would likely indicate that the sensor was installed backwards. In some embodiments, software implementations can associate the appropriate coefficients for power measurements to ensure that the correct polarity is being applied in subsequent calculations. This process can be performed remotely without requiring any physical changes to the on-site hardware configuration. It should be appreciated that scaling this process over thousands of PV systems can save considerable time, man power, and resources.

In certain embodiments, a method can include requesting power measurement data to measure a power signal from a power generation site (e.g., photo-voltaic (PV) system) on an electrical grid, wherein the data is requested during a predetermined time period. The measurement data can include a first power measurement corresponding to a first phase of the power signal, a second power measurement corresponding to a second phase of the power signal, and (where applicable) a third power measurement corresponding to a third phase of the power signal. The method can further include receiving, from the PV system, the power measurement data during the predetermined time period. In one example, the predetermined time period can be between midnight and 2 A.M. For each power measurement, the method can include associating a negative coefficient with the power measurement if it is less than zero, and associating a positive coefficient with the power measurement if it is equal to or greater than zero. The method can further include calculating a power measurement for the power generation site based, in part, on the associated coefficients for each phase of the power signal. In some embodiments, the power signal measurement data can be measured by a number of current transducers, each current transducer being associated with a phase of the power signal. Power measurements can be measured using both a voltage and current meter (e.g., current transducer), a current meter (plus a known voltage), a current meter and load meter, any combination thereof, or any other methods of measuring power as would be appreciated by one of ordinary skill in the art.

In certain embodiments, a computer-implemented method for measuring power at an EG site includes requesting, by a processor, power measurement data from a power meter during a predetermined time period. The power meter may be configured to measure power usage from the EG site including power provided by an electrical utility grid and an EG system at the EG site. The method may further include receiving, by the processor from the power meter, the power measurement data and associating, by the processor, one or more coefficients with the power measurement data based on the direction of the net power flow from the EG site. The method may further include calculating, by the processor, a power measurement for the energy generation site based, in part, on the associated coefficient. In some implementations, the method further includes associating, by the processor, a negative coefficient with the power measurement data if the power measurement is less than zero, and associating, by the processor, a positive coefficient with the power measurement data if the power measurement is equal to or greater than zero.

The power measurement data can include a first power measurement corresponding to a first phase of power, a second power measurement corresponding to a second phase of power, and a third power measurement value corresponding to a third phase of power, where associating the negative coefficient or the positive coefficient with the power measurement data applies to both the first and second phases of power. The predetermined time period may occur during a period when the EG system generates its lowest power levels, or during a period of substantially no sunlight if the EG system includes PV power. The power meter(s) can be or include a current transducer. Separate power meters can measure multiple power measurements (e.g., first/second/third phase measurement). In some cases, a single power meter may include multiple channels to measure each phase.

In some embodiments, a system includes one or more processors, and one or more non-transitory computer-readable storage mediums containing instructions configured to cause the one or more processors to perform operations including generating a request, by the one or more processors, to receive power measurement data from a power meter at an EG site during a predetermined time period, where the power meter is configured to measure power usage from the EG site including power provided by an electrical utility grid, and an EG system at the EG site. The system can further include instructions performed by the one or more processors that include sending the request to the power meter, receiving the power measurement data, associating one or more coefficients with the power measurement data based on the direction of the net power flow from the EG site, and calculating a power measurement for the energy generation site based, in part, on the associated coefficient. The associating can be performed on subsequent power measurement data received from the power meter. The association of the one or more coefficients with the power meter can be stored in a database.

The system can further include instructions performed by the one or more processors that include associating a negative coefficient with the power measurement data if the power measurement is less than zero, and associating a positive coefficient with the power measurement data if the power measurement is equal to or greater than zero. In some cases, the power measurement data can include a first power measurement corresponding to a first phase of power, and second power measurement corresponding to a second phase of power, and a third power measurement corresponding to a second phase of power, where associating the negative coefficient or the positive coefficient with the power measurement data applies to each measured phase of power. The predetermined time period may occur during a period when the EG system generates its lowest power levels, or during a time of historically lowest levels of PV-based energy generation.

In further embodiments, a computer-implemented method for measuring power at an EG site can include requesting, by a processor, power measurement data from a power meter during a predetermined time period, where the power meter is configured to measure power usage from the EG site including power provided by an electrical utility grid, and an EG system at the EG site. The method can further include receiving, by the processor from the power meter, the power measurement data, associating power provided by the electrical utility grid with a first coefficient having a first polarity, and associating power provided by the EG system with a second coefficient having a second polarity different from the first polarity, where the associating the power measurement data with the first or second polarities is performed on subsequent power measurement data received from the power meter. The method can further include determining whether a net power flow from the electrical utility grid and the EG system is of the first polarity or the second polarity, and calculating a power measurement for the power generation site based, in part, on the associated coefficients. In some cases, the predetermined time period occurs during a period when the EG system generates its lowest daily power levels.

### BRIEF DESCRIPTION OF THE DRAWINGS

FIG. 1 shows a simplified block diagram of a system environment, according to certain embodiments of the invention.

FIG. 2 shows a simplified diagram of a typical electrical panel for a power system, according to certain embodiments of the invention.

FIG. 3 shows a simplified diagram of a power system including a main panel and a power meter, according to certain embodiments of the invention.

FIG. 4 shows a simplified diagram of a power system including a main panel and a power meter, according to certain embodiments of the invention.

FIG. 5 shows a system with power meter coupled to main power line, according to certain embodiments of the invention.

FIG. 6A shows a single-phase power line, according to certain embodiments of the invention.

FIG. 6B shows a dual phase power line, according to certain embodiments of the invention.

FIG. 6C shows a three-phase power line, according to certain embodiments of the invention.

FIG. 7 shows a simplified diagram showing power meter installation points in an electrical panel for a power system, according to certain embodiments of the invention.

FIG. 8 shows a simplified diagram illustrating aspects of measuring a current in an electrical panel, according to certain embodiments of the invention.

FIG. 9 shows a simplified flow chart for a method of measuring a power signal in a power grid, according to certain embodiments of the invention.

FIG. 10 shows a simplified flow chart for a method of measuring a power signal in a power grid, according to certain embodiments of the invention.

FIG. 11 shows a graph illustrating a typical predetermined time period for receiving power measurement data for one or more power meters in a PV-based energy generation system, according to certain embodiments of the invention.

FIG. 12 shows a simplified block diagram of a computer system, according to an embodiment of the present invention.

### DETAILED DESCRIPTION

The present disclosure relates in general to energy generation systems and/or energy consuming systems, and in particular to determining the location of a load meter for monitoring such systems.

In the following description, for purposes of explanation, numerous examples and details are set forth in order to provide an understanding of embodiments of the present invention. It will be evident to one skilled in the art that certain embodiments can be practiced without some of these details, or can be practiced with modifications or equivalents thereof.

Systems and methods of the invention can determine a load meter installation orientation in a grid-connected EG system (e.g., a photo-voltaic-based energy generation system) at a site to accurately determine a net load. An improperly installed load meter (e.g., installed backwards) will report power measurements that are inverted (incorrect polarity) rendering net power readings that include utility and EG system energy contributions to be incorrect. In some embodiments, after a load meter in installed, a server (e.g., a gateway computer) may request power measurement data from a power meter at the site during a predetermined time period, such as midnight to 2 A.M., so that any power flow into the grid-connected EG system can be assured to be provisioned by the utility grid and not from the PV panels at the site because little to no sunlight is converted into electricity during that period of time. The server then receives the power measurement data from the load meter and, if necessary, associates a correction coefficient to any further data received from that power meter. Finally, a power measurement can be calculated for the power generation site based, in part, on the associated coefficients. This can be advantageous as subsequent power readings are then corrected and there is no need to have a service technician return to the installation site to correct the orientation of the power meter.

As mentioned above, the power meter can be configured to measure power usage from the EG site including power provided by an electrical utility grid and an EG system at the EG site. For some residential installation sites, the power measurement data may include a first power measurement corresponding to a first phase of power and a second power measurement corresponding to a second phase of power. In certain commercial installation sites, the power measurement data may include a first power measurement corresponding to a first phase of power, a second power measurement corresponding to a second phase of power, and a third power measurement corresponding to a third phase of power.

For purposes of illustration, several of the examples and embodiments that follow are described in the context of EG systems that use solar PV technology for energy generation and battery technology for energy storage. However, it should be appreciated that embodiments of the present invention are not limited to such implementations. For example, in some embodiments, alternative types of energy generation technologies (e.g., wind turbine, solar-thermal, geothermal, biomass, hydropower, etc.) may be used. In other embodiments, alternative types of energy storage technologies (e.g., compressed air, flywheels, pumped hydro, superconducting magnetic energy storage (SMES), etc.) may be used. One of ordinary skill in the art will recognize many modifications, variations, alternatives, as well as the application of the concepts described herein to such modifications, variations, and alternatives.

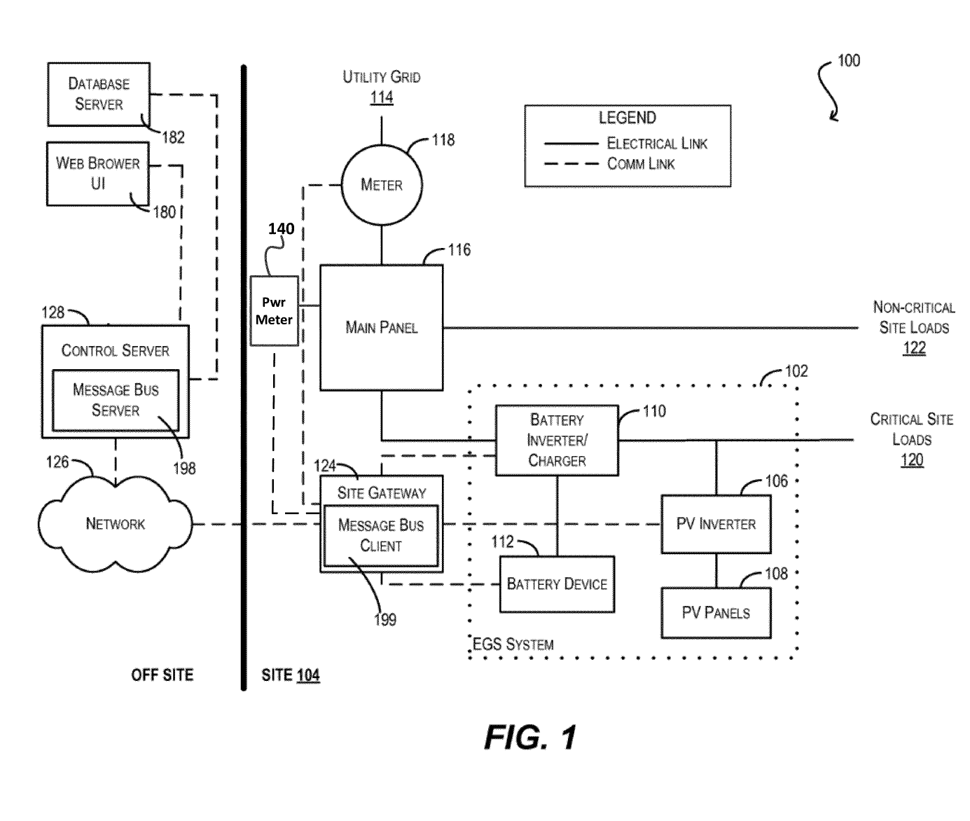

FIG. 1 shows a simplified block diagram of system environment 100, according to an embodiment of the present invention. As shown, system environment 100 can include energy generation and storage (EGS) system 102 that is installed at site 104 (e.g., a residence, a commercial building, etc.). EGS system 102 includes a PV-based energy generation subsystem that can include a PV inverter 106, one or more PV panels 108, and a battery-based energy storage subsystem comprising battery inverter/charger 110 and battery device 112. In some embodiments, PV inverter 106 and battery inverter/charger 110 can be combined into a single device. In the example of FIG. 1, EGS system 102 is grid-connected; thus, PV inverter 106 and battery inverter/charger 110 are electrically connected to utility grid 114 via main panel 116 and utility meter 118. Further, to provide power to site 104, utility grid 114, PV inverter 106, and battery inverter/charger 110 can be electrically connected to critical site loads 120 and non-critical site loads 122.

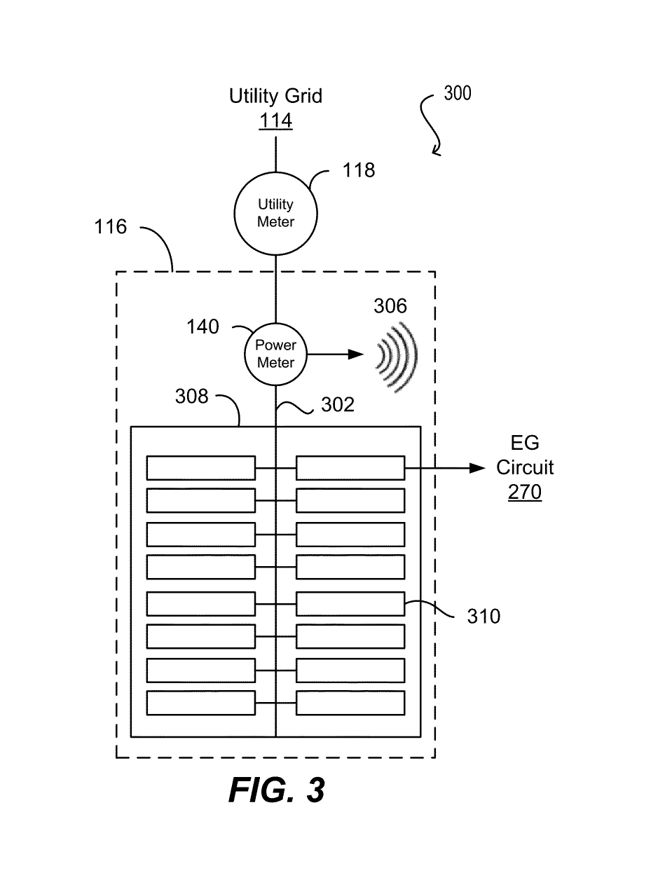

System environment 100 can include power meter 140 that is electrically connected to utility grid 114 and EGS system 102 via main panel 116. A power meter can be used to measure the magnitude and polarity of power being delivered to and from a load (e.g., loads 120, 122). Power meter 140 is typically located at or near the main panel for convenient access to the main power line, however other configurations are anticipated, as would be appreciated by one of ordinary skill in the art. Power meters can be referred to as a load meter or a load-metering device. Power meter 140 is further discussed below at least with respect to FIGS. 3-5 and 7-10.

Integrated EGS systems, such as system 102, can provide one or more advantages over energy generation systems that do not incorporate on-site energy storage. For example, excess energy produced by PV components 106 and 108 can be stored in battery device 112 via battery inverter/charger 110 as a critical reserve. Battery inverter/charger 110 can then discharge this reserved energy from battery device 112 when utility grid 114 is unavailable (e.g., during a grid blackout) to provide backup power for critical site loads 120 (and/or non-critical site loads 122) until grid power is restored. As another example, battery device 112 can be leveraged to “time shift” energy usage at site 104 in a way that provides economic value to the site owner or the installer/service provider of EGS system 102. For instance, battery inverter/charger 110 can charge battery device 112 with energy from utility grid 114 (and/or PV inverter 106) when grid energy cost is low. Battery inverter/charger 110 can then dispatch the stored energy at a later time to, e.g., offset site energy usage from utility grid 114 when PV energy production is low/grid energy cost is high, or sell back the energy to the utility when energy buyback prices are high (e.g., during peak demand times).

Centralized or remote management of an EGS system, such as system 102, can be advantageous for large scale EG networks for residential, commercial, or industrial markets. System 102, for example, can incorporate a centralized management system that includes site gateway 124 and control server 128. Site gateway 124 is a computing device (e.g., a general purpose personal computer, a dedicated device, etc.) that is installed at site 104. Gateway 124 may be a single gateway or a network of gateways and may be configured physically at the installation site or remotely, but in communication with site 104. As shown, site gateway 124 is communicatively coupled with on-site components 106, 110, 112, 118, and 140, as well as with control server 128 via network 126. In one embodiment, site gateway 124 can be a standalone device that is separate from EGS system 102. In other embodiments, site gateway 124 can be embedded or integrated into one or more components of system 102. Control server 128 is a server computer (or a cluster/farm of server computers) that is remote from site 104. Control server 128 may be operated by, e.g., the installer or service provider of EGS system 102, a utility company, or some other entity.

In one embodiment, site gateway 124 and control server 128 can carry out various tasks for monitoring the performance of EGS system 102. For example, site gateway 124 can collect system operating statistics, such as the amount of PV energy produced (via PV inverter 106), the energy flow to and from utility grid 114 (via utility meter 118), the amount of energy stored in battery device 112, and so on. Site gateway 124 can then send this data to control server 128 for long-term logging and system performance analysis.

Site gateway 124 and control server 128 can operate in tandem to actively facilitate the deployment and control of EGS system 102. Specifically, FIG. 1 shows other entities remote from the site “OFF SITE”, which may communicate with EGS system 102. These other entities include web server 180 and database server 182. These entities are not discussed as their contribution to the operation of system 100 are not germane to the novel aspects discussed herein and would otherwise be understood by those of ordinary skill in the art.

According to embodiments, communication between the various elements involved in power management (e.g., between the centralized control server and the various devices at the remote site, and/or between centralized control server 128 and various other remote devices such as the database server, web server, etc.) may be achieved through use of a power management Message Bus System (MBS). In the simplified view of FIG. 1, the MBS is implemented utilizing message bus server 198, and message bus client 199 located at the site gateway. In FIG. 1, the message bus server is shown as being on control server 128, but this is not required and in some embodiments the message bus server could be on a separate machine and/or part of a separate server cluster.

The power management MBS as described herein, facilitates communication between the various entities (e.g., on-site devices, central control systems, distributed control systems, user interface systems, logging systems, third party systems etc.) in a distributed energy generation and/or storage deployment. The MBS operates according to a subscribe/publish model, with each respective device functioning as a subscriber and/or publisher, utilizing a topic of a message being communicated.

It should be appreciated that system environment 100 is illustrative and not intended to limit embodiments of the present invention. For instance, although FIG. 1 shows control server 128 as being connected with a single EGS system at a single site, control server 128 can be simultaneously connected with a fleet of EGS systems that are distributed at multiple sites. In these embodiments, control server 128 can coordinate the scheduling of these various systems/sites to meet specific goals or objectives. In further embodiments, the various components depicted in system 100 can have other capabilities or include other subcomponents that are not specifically described. Furthermore, multiple instances and variants of the control server may exist, each communicating with one or more other control servers, EGS systems and/or other devices connected to the MBS. Alternatively, other methods of communication (e.g., point-to-point) other than MBS-based systems can be used, and one of ordinary skill in the art will recognize the many variations, modifications, and alternatives in methods of communication to implement system 100.

### Power Meters and Installation Locations

In certain embodiments, a power meter can be used to measure the magnitude and polarity of power being delivered to and from a load (e.g., site loads 120, 122). For example, some sites may draw power from the utility grid during periods of peak power requirements. Although the PV system is generating power, the load requirements may be greater than the power being generated by the PV system, resulting in a net positive current flow into the site from the utility grid. In contrast, load requirements may be lower than the power being generated by the PV system during times of low power use, resulting in a net negative current flow out of the site and into the utility grid. Power meter 140 of FIG. 1 illustrates one example of how a power meter may be coupled to a grid-connected EG system.

In some implementations, a power meter measures the power being delivered to the load at the electrical panel and wirelessly transmits the collected data to a local site gateway. This can provide users with remote access and smart metering capabilities.

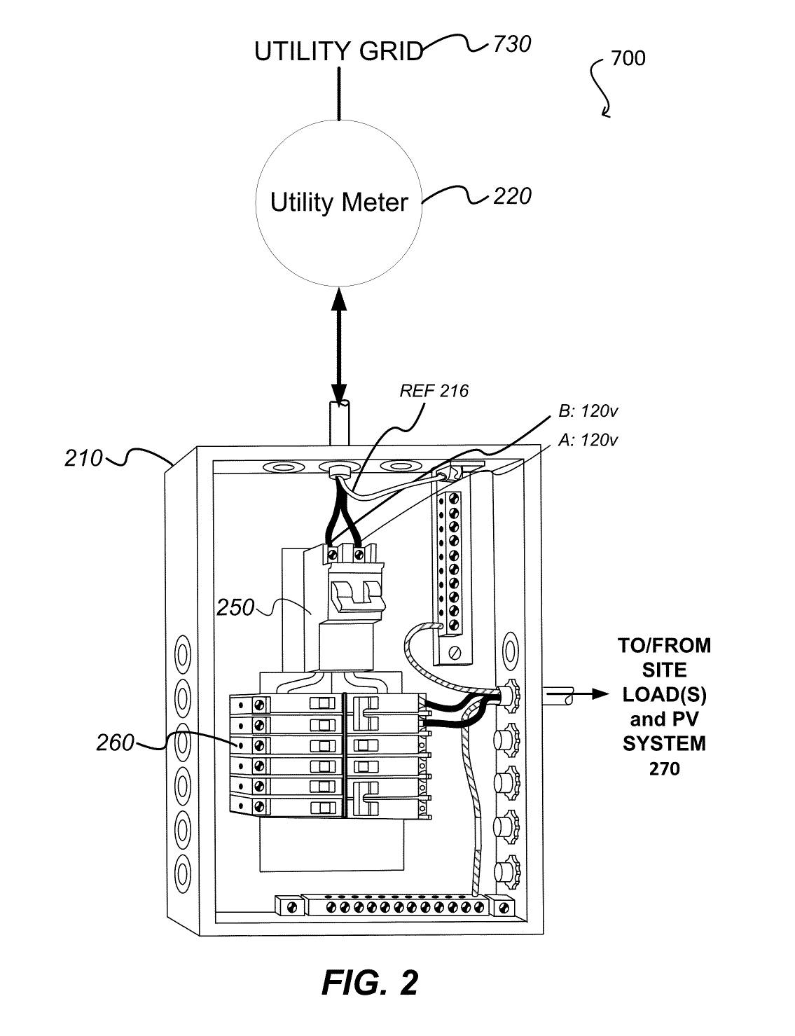

FIG. 2 shows a simplified diagram of a typical electrical panel 210 for power system 200, according to certain embodiments of the invention. Electrical panel 210 includes main disconnect switch 250, breaker box 260, and power bus 270. A number of individual circuits 260 are shown branching off the main line, however only once is being used in this example (power bus 270). It should be understood that some embodiments may or may not include breaker boxes, main disconnect switches, or the like. Power bus 270 can power any suitable load, such as loads 122 and 120 of FIG. 1. Although it is not explicitly shown, electrical panel 210 can be connected to an EGS (e.g., a PV-based power system), such as EGS 102 of FIG. 1. Thus, power can be coming into the system via the utility grid 230 or out of the system via an EG system (e.g., PV system) depending on the output power of the PV system and the requirements of the system load. Electrical panel 210 can be connected to the utility grid 230 through utility meter 220.

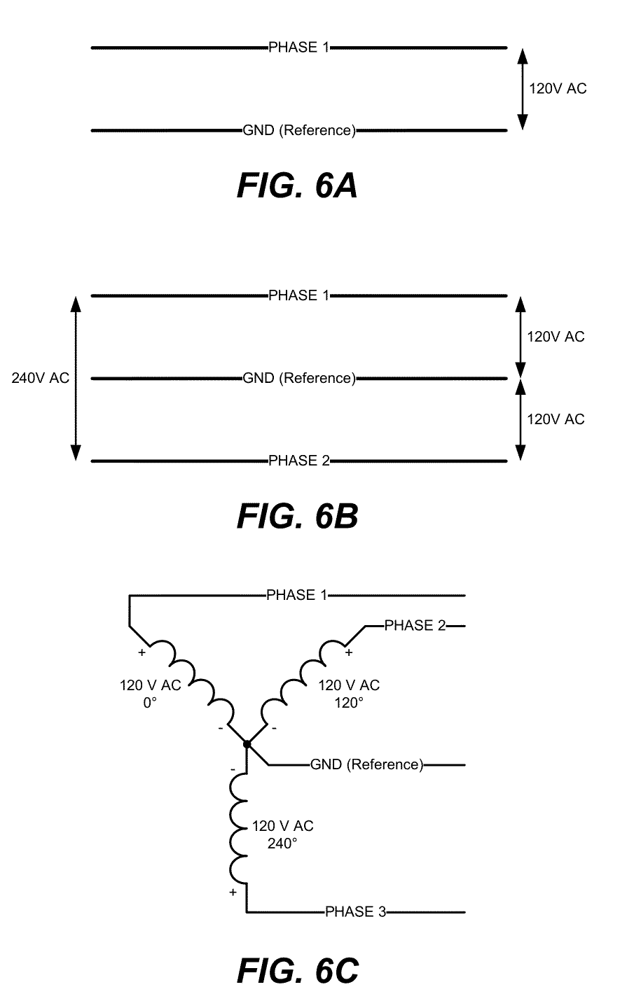

Electrical panel 210 can include power leads A and B, which can create 240V across both leads or 120V for each lead with respect to reference 216. Reference 216 can be coupled to the neutral bus bar, which in turn can be coupled to the ground bus bar. Power lead A can be a voltage of a first phase (referred to as “phase A”). Power lead B can be a voltage of a second phase (referred to as “phase B”). Electrical systems comprising single phase or 3-phase power are anticipated and the embodiments described herein can accommodate these systems. One, two, and three phase systems are further discussed below at least with respect to FIGS. 6A-6C. Although multiples of 120V AC are described herein, it should be understood that any suitable voltage levels can be used and these examples are not intended to be limiting, but rather illustrative of certain common residential wiring configurations.

Utility meter 220 is typically hardwired and operated by a utility company operating the utility grid. The power meter installations and configurations described herein include different meter(s) that are coupled to the power system 200. Electrical panels come in a wide variety of shapes and sizes. As a result, power meters may be coupled to power systems in a variety of different configurations. The non-uniform power meter installations across different systems may create a higher likelihood that some power meters may be installed backwards, which can cause inaccurate power measurement readings. This typically manifests in power measurements having the wrong polarity. For example, an incorrectly installed power meter may read a positive power measurement, which can indicate power being supplied by the utility grid when, in fact, it should be a negative power measurement indicating power generated by a local EG system being pushed back to the grid. Some of the different installation locations and configurations are discussed below at least with respect to FIGS. 3-5.

FIG. 3 shows a simplified diagram of a power system 300 including main panel 116 (from FIG. 1) and power meter 140, according to certain embodiments of the invention. Power meter 140 is typically coupled to a main power line 302 in a location housed by main panel 116. Power line 302 allows power to flow from the utility grid 114 into main panel 116. Main panel 116 is connected to the utility grid 114 through utility meter 118. Power meter 140 can communicate with gateway 124 through hardwired connection or by a wireless communication protocol (e.g., Zigbee, Wi-Fi, Bluetooth, RF, etc.).

Main panel 116 can include a main disconnect switch (not shown), breaker box 308, and a power bus (not shown). Main panel 116 can include a number of individual circuits 310 to power various loads at the site, with each circuit having an individual breaker. The power bus can be an arrangement of gauges of wires that power any suitable load, such as loads 120 and 122. Main panel 116 can be connected to an EG system (e.g., a PV-based power system), such as EG system 102 of FIG. 1. Thus, power can be supplied to system 200 via the utility grid 114 as well as the EG system (e.g., PV system) via EG circuit 270.

Power meter 140 can be coupled to power line 202 to measure power supplied to main panel 116. The measured power may correspond to power drawn from the site load(s). Power meter 140 may be any suitable measurement device, however typical embodiments do not physically splice power line 302 for in-line measurements, which is generally disfavored. In exemplary embodiments, power meter 140 can include a current transducer (CT) that measures current running through power line 202.

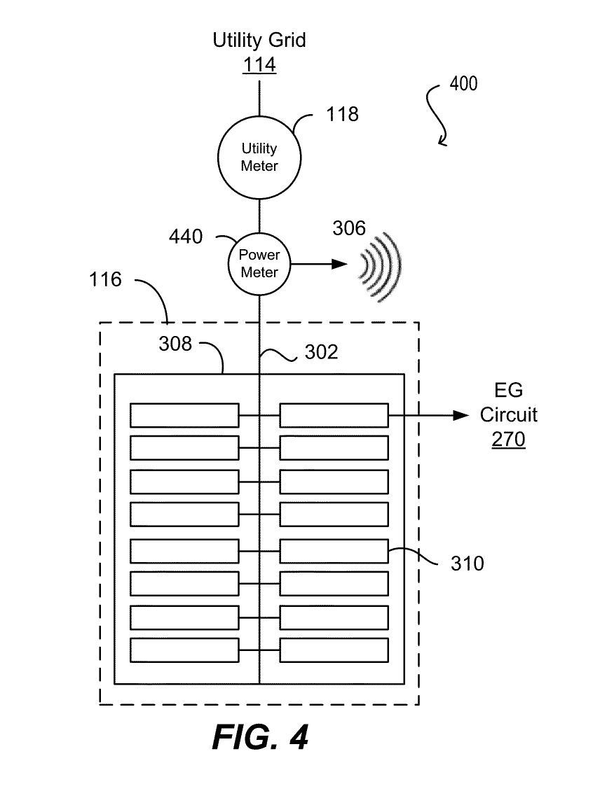

In some embodiments, power meter(s) 140 may be installed within main panel 116. This may allow power meter 140 to be better protected from the environment. However, installation inside of a main panel may not be possible due to size constraints (sometimes multiple power meters are installed), regulatory constraints (installers may not be legally allowed to tamper with or connect to circuits inside main panel 116), or other restrictions. The difficulties of physically installing multiple power meters inside of a main panel may account for some of the installation errors. Thus, some systems may include power meters installed outside of the main panel 116, as shown in FIG. 4. It should be understood that any suitable power meter installation location is possible, as would be appreciated by one of ordinary skill in the art.

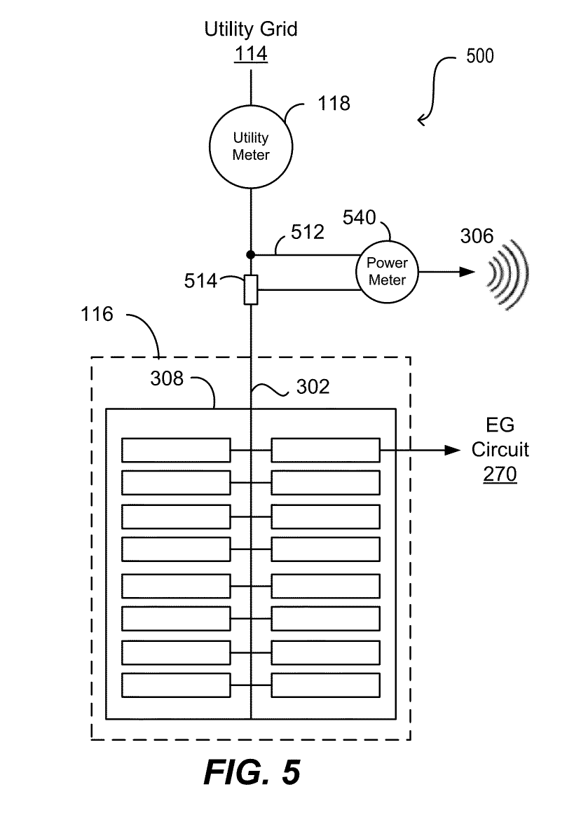

FIG. 5 shows system 500 with power meter 540 coupled to main power line 202, according to certain embodiments of the invention. Power meter 540 can include a current transducer 514 to measure current flow though main power line 302. A voltage tap 512 can be used to directly measure the voltage on main power line 302. Direct measurement may be possible by physically splicing the voltage tap to the main line, or other suitable method of physical connection. In some embodiments, voltage tap 512 senses voltage drawn by the main panel 116 from the main power line 302.

Current transducer 514 can measure current flow through main power line 302 by detecting magnetic fields generated by current flow through the main power line 302. In certain embodiments, current transducer 514 may be a coil of wire that wraps partially or entirely around the main power line 202 without actually touching the main power line 302. Accordingly, power meter 140 may measure power (e.g., voltage and current) utilized by the main panel 116 through the main power line 302.

### One-, Two-, and Three-Phase Power

FIG. 6A shows a single-phase power line, according to certain embodiments of the invention. Single-phase power typically refers to a two-wire Alternating Current (AC) power circuit. Typically, there is one power wire (“phase 1”) and one neutral wire. In the United States, 120 VAC is the standard single-phase voltage with one 120 VAC power wire and one neutral (e.g., ground) wire. In some countries, 230 VAC is the standard single-phase voltage with one 230 VAC power wire and one neutral wire. Power flows between the power wire (through the load) and the neutral wire.

FIG. 6B shows a dual phase power line, according to certain embodiments of the invention. Dual-phase or split-phase power is also single phase because it is a two-wire Alternating Current (AC) power circuit. In the U.S., this is the standard household power configuration with two 120 VAC power wires (Phase A, Phase B—180 degrees out of phase with one another) and one neutral wire (e.g., reference and/or ground wire). This configuration provides (2) 120 VAC and (1) 240 VAC power circuits, as shown in FIG. 6B. That is, 120 VAC can flow between either power wire (through the load) and the neutral wire, or 240 VAC power can flow between the two power wires (through the load). This wiring configuration is used in most U.S. households because of its flexibility. Low power loads (e.g., lights, TV, etc.) are powered using either 120 VAC phases and high power loads (e.g., water heaters, HVAC systems, etc.) may be powered using the 240 VAC power circuit.

FIG. 6C shows a three-phase power line, according to certain embodiments of the invention. Three-phase power refers to three-wire Alternating Current (AC) power circuits. Typically, there are three power wires ((Phase A, Phase B, Phase C—each 120 degrees out of phase with one another) and one neutral wire (e.g., reference, ground). In many U.S. industrial and/or commercial structures, three-phase power is the standard power configuration, typically utilizing 3-Phase, 4-wire 208 VAC/120 VAC power circuit. This arrangement provides (3) 120V single-phase power circuits and (1) 208V three-phase power circuit. That is, 120 VAC power can flow between any power wire (through the load) and the neutral wire. Alternatively, 208 VAC power can flow between the three power wires (through the load). Most U.S. commercial buildings use a 3 Phase 4 Wire 208Y/120V power arrangement because of its flexibility. Low power loads (lights, computers, etc.) are powered using any 120V single-phase power circuit and high power loads (e.g., water heaters, AC compressors) are powered using the 208V three-phase power circuit. As mentioned above, most U.S. industrial facilities use a 3-Phase, 4 Wire 480Y/277V power arrangement because of its power density. Compared to single-phase power circuits, three-phase power circuits provide 1.732 (the square root of 3) times more power with the same current. Using a 3-phase power arrangement may save on electrical construction costs by reducing the current requirements, the required wire size, and the size of associated electrical devices. Furthermore, 3-phase power may also reduce energy costs because the lower current reduces the amount of electrical energy lost to resistance (i.e., heat).

### Power Meter Orientation and Detection

Current sensors (e.g., current transducers) are typically configured according to a particular polarity. When EG systems are installed, technicians often times install one or more of the current sensors backwards, which can cause power measurements to be wrong because of the incorrect polarity. This can happen even with clear labeling or other indicators that are intended to prevent current transducers from being placed backwards. Some current transducers even include LEDs that light up when they are supposedly installed in the correct configuration. However, current measurements can still be wrong if, e.g., the technician forgets to power off a local PV system when testing the installation. Typically, when this occurs, the mistake is usually evident after installation and a service technician has to return to the site to correct the problem (e.g., flip the current transducer). This can be costly and very time consuming, especially when this occurs on thousands of systems. However, embodiments of the present invention can determine the configuration of the current measurement devices and correct their polarity without requiring reinstallation, as further discussed below.

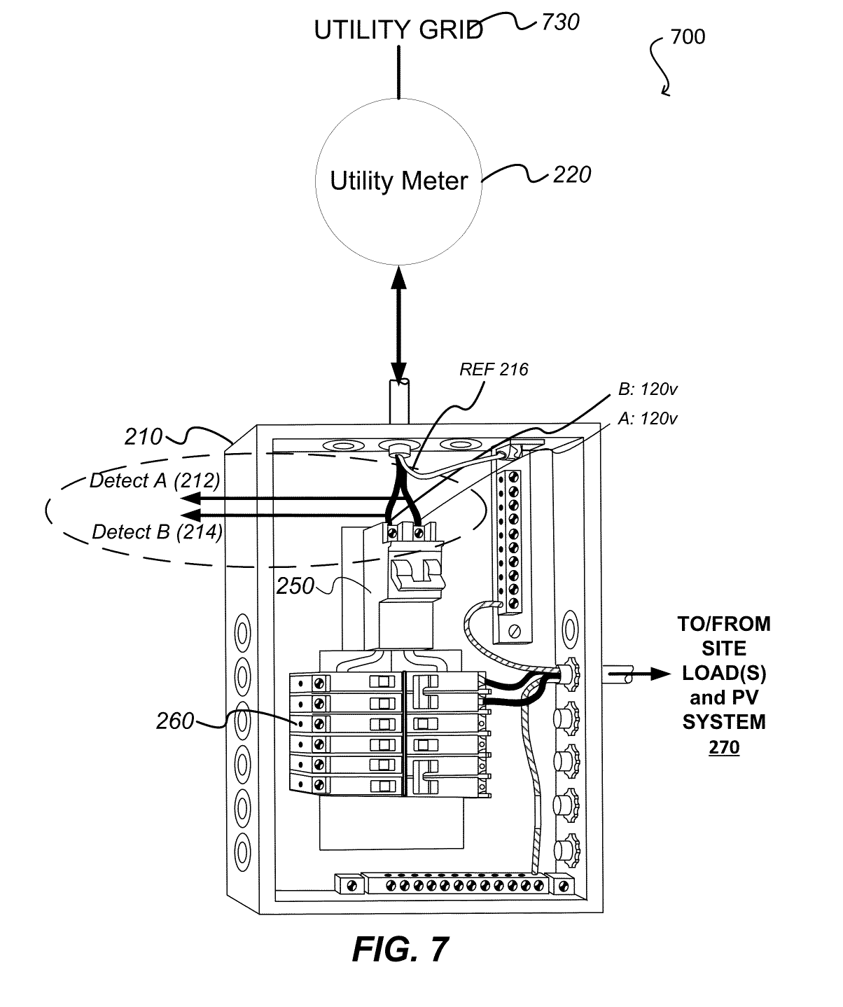

FIG. 7 shows a simplified diagram showing power meter installation points in an electrical panel 210 for a power system, according to certain embodiments of the invention. Power meters are typically coupled to the electrical main in a location housed by an electrical panel. Electrical panel 210 is connected to the utility grid 230 through utility meter 220. Electrical panel 210 includes power leads A and B, which can create 240V across both leads or 120V for each lead with respect to reference 816, as discussed above with respect to FIG. 6B. Power lead A can be a voltage of a first phase (referred to as “phase A”). Power lead B can be a voltage of a second phase (referred to as “phase B”). Electrical systems comprising single-phase or 3-phase power are anticipated and the embodiments described herein can be similar applied to these systems. Furthermore, any suitable voltage (e.g., 120 VAC, 220 VAC, etc.) can be used in a power system as would be appreciated by one of ordinary skill in the art.

A power meter (not shown) can be coupled to the electrical panel 810 at sites 812 (phase A) and 814 (phase B) to measure a current in the electrical main. Main line power can be monitored by indirectly measuring the current running through the main by one or more current transducers along with voltage measurement. This eliminates the need to directly place a meter in-line with the main, which is generally not favored. The power meter can be a sub meter. In some cases, Phase A and Phase B can be positive and negative terminals, or vice versa. Meter installation locations are further addressed above, for example, in FIGS. 3-5.

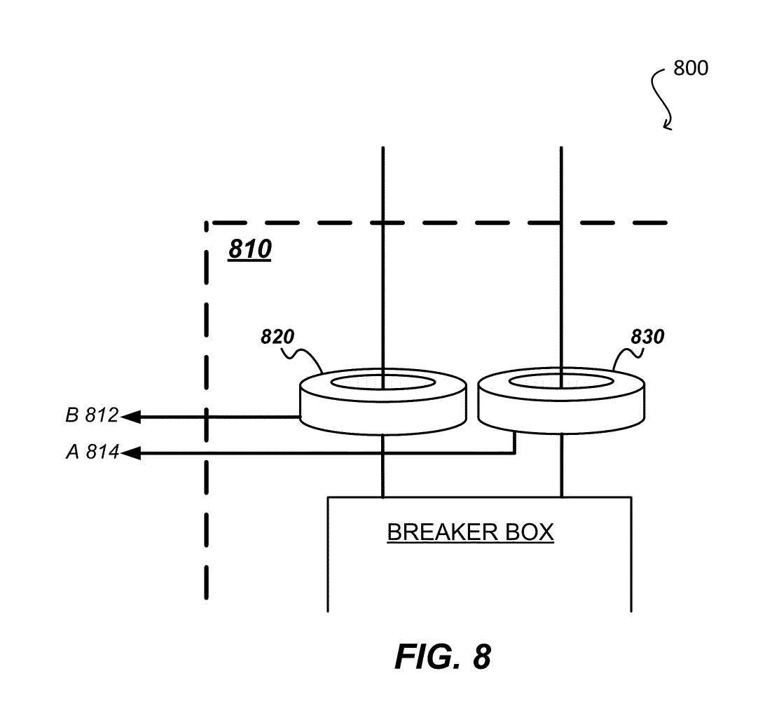

FIG. 8 shows a simplified diagram illustrating aspects of measuring a current in an electrical panel 810, according to certain embodiments of the invention. A 2-phase electrical main is shown, which is a typical wiring configuration for residential structures (see also FIG. 6B). A current sensor (e.g., current transducer 830) is electromagnetically coupled to phase A of the electrical main. Similarly, a second current sensor (e.g., current transducer 820) is electromagnetically coupled to phase B of the electrical main. Thus, each current transducer measures a current in each phase of the electrical main without the need for direct electrical coupling. The measured current from current transducers 820 and 830 can be fed to a power meter (e.g., power meter 140 of FIG. 1) for further processing. In some embodiments, the power meter can send the measurement data to a remote site via a local site gateway (e.g., site gateway 124 of FIG. 1). The power meter can be physically and/or wirelessly coupled to any suitable entity, as required by design. In certain embodiments, the number of power meters may equal the number of phases. For example, a 3-phase system may include three power meters—one for each phase. Some implementations may include a single power meter having multiple channels to measure each phase. Furthermore, some embodiments may use separate current and voltage meters to determine a power measurement (and some may use load meters for I²R power calculations). The myriad possibilities and configurations for measuring power in an EG system would be appreciated by one of ordinary skill in the art.

In some embodiments, EG systems can generate electrical power to drive a load. When the power generated by the EG system is greater than the power required by the load, the excess power can be routed to the utility grid resulting in a negative power as measured by the current sensors (e.g., current transducers). Likewise, when the power generated by the EG system is less than the power required by the load, the resulting power is generated primarily by the utility grid resulting in a positive power as measured by the current sensors. Some systems may associate incoming power as negative power and outgoing power as positive power.

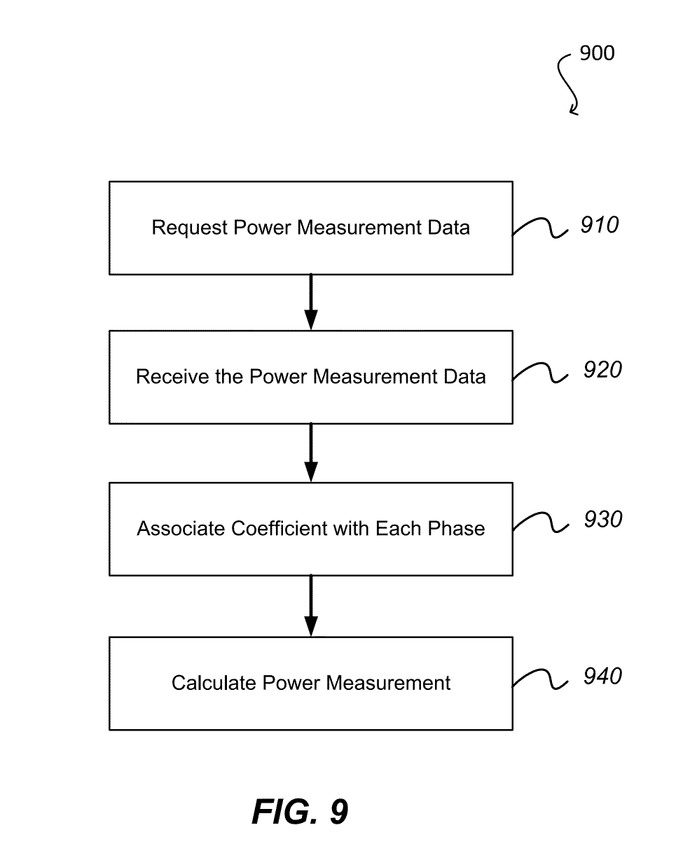

FIG. 9 shows a simplified flow chart for a method 900 of measuring a power signal in a power grid, according to certain embodiments of the invention. Method 900 can be performed by processing logic that may comprise hardware (circuitry, dedicated logic, etc.), software (such as is run on a general purpose computing system or a dedicated machine), firmware (embedded software), or any combination thereof. In one embodiment, a processor on control server 128, site gateway 124, or other suitable computing device can perform method 900.

In step 910, power measurement data is requested for the purpose of measuring a power signal from a photo-voltaic (PV) system on an electrical grid. The data can be requested during a predetermined time period. In one non-limiting example, the predetermined time period can be between midnight to 2 A.M., although other time periods are possible. Preferably, the predetermined time period includes times when there is little to no sunlight. This will ensure that the only power entering the system will be from the utility, because the EG system (e.g., PV system) will not be able to generate enough power to overcome the load and push back into the grid. The measurement data can include a first current or power measurement corresponding to a first phase of the power signal. For example, a first measurement can include a current measured by a current transducer, such as sensor 830 of FIG. 8. The measurement data can further include a second current power measurement corresponding to a second phase of the power signal. For example, a second measurement can include a current measured by sensor 820 of FIG. 8. Although this example describes a two-phase power system (typically found in residential systems), these principles can apply to single-phase or other multi-phase (e.g., 3-phase systems) as well.

At step 920, measurement data is received from the PV system during the predetermined time period. At step 930, for each current or power measurement, a negative coefficient is associated with the power or current measurement if it is less than zero (i.e., the power meter is installed backwards with an incorrect polarity), and a positive coefficient is associated with the power measurement if it is equal to or greater than zero (i.e., the power meter is installed correctly with a correct polarity). At step 940, a power measurement for the PV system is calculated and is based, in part, on the associated coefficients for each phase of the power signal. For instance, power measurements for each phase that is determined to be installed backwards may be multiplied by (−1) to ensure that the measurement has the correct polarity. Conversely, power measurements for each phase that is determined to be installed correctly may be multiplied by +1 so no change is made to the measurement.

In some embodiments, the power signal measurement data can be measured by a plurality of current transducers (i.e., current measuring sensor), each current transducer being associated with a phase of the power signal. In some non-limiting embodiments, the coefficients can be calculated as follows:

if power at time t on phase A is <0:

(coefficient a=−1);

else

(coefficient a=1). (1)

if power at time t on phase B is <0:

(coefficient b=−1);

else

(coefficient b=1). (2)

if power at time t on phase C (if applicable) is <0:

(coefficient c=−1);

else

(coefficient c=1). (3)

In subsequent measurements, power measurements as follows:

Power of A_{how}=power A_{now}*coefficient A. (4)

Power of B_{now}=power B_{now}*coefficient B. (5)

Power of C_{now}=power C_{now}*coefficient C. (6)

Thus, in subsequent calculations, the appropriate coefficient is applied regardless of the configuration of the sensor. That is, the current can be measured remotely (e.g., from a control server) during a predetermined time period when EG power is typically low (e.g., sun down). Based on the resulting power measurement, the correct polarity of the current is anticipated and can be used to determine whether the corresponding current or power sensor was installed correctly. A coefficient is permanently applied to the phase measurement in subsequent calculations thereby eliminating the need to physically swap out or flip the polarity of the current or power-sensing device.

In an alternative embodiment, a coefficient is only applied to phase measurements that are determined to be incorrectly installed (i.e., having the wrong polarity). No coefficient is applied to correctly installed sensors, as a coefficient of (1) is implied.

It should be appreciated that the specific steps illustrated in FIG. 9 provide a particular method 900 of measuring a power signal in a power grid, according to certain embodiments of the present invention. Other sequences of steps may also be performed according to alternative embodiments. For example, alternative embodiments of the present invention may perform the steps outlined above in a different order. Moreover, the individual steps illustrated in FIG. 9 may include multiple sub-steps that may be performed in various sequences as appropriate to the individual step. Furthermore, additional steps may be added or removed depending on the particular applications. One of ordinary skill in the art would recognize and appreciate many variations, modifications, and alternatives of the method 900.

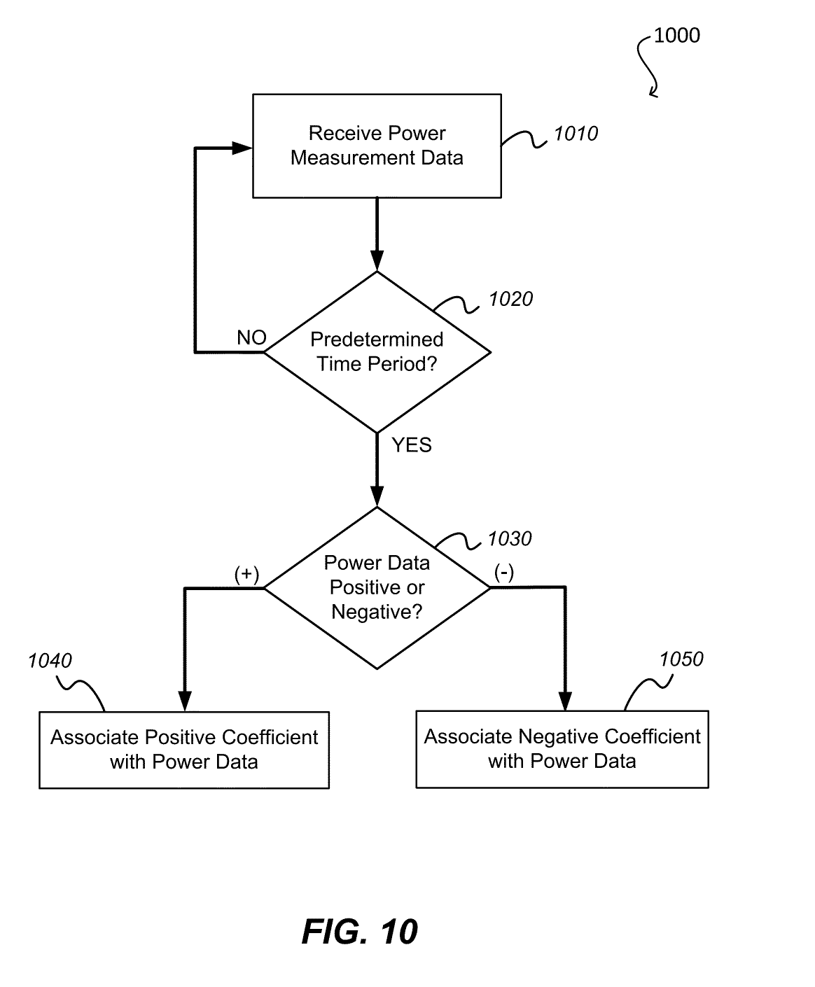

FIG. 10 shows a simplified flow chart for a method 1000 of measuring a power signal in a power grid, according to certain embodiments of the invention. Method 1000 can be performed by processing logic that may comprise hardware (circuitry, dedicated logic, etc.), software (such as is run on a general purpose computing system or a dedicated machine), firmware (embedded software), or any combination thereof. In one embodiment, a processor on control server 128, site gateway 124, or other suitable computing device can perform method 1000.

At step 1010, power measurement data is requested (e.g., from system 102) to measure a power signal from a photo-voltaic (PV) system on an electrical grid. The measurement data can include a first current or power measurement corresponding to a first phase of the power signal. For example, a first measurement can include a current measured by a current transducer, such as sensor 830 of FIG. 8. The measurement data can further include a second current power measurement corresponding to a second phase of the power signal. For example, a second measurement can include a current measured by sensor 820 of FIG. 8. Although this example describes a two-phase power system (typically found in residential systems), these principles can apply to single-phase or other multi-phase systems (e.g., 3-phase) as well.

At step 1020, it is determined whether the power measurement data is received during the predetermined time period. In one non-limiting example, the predetermined time period can be between midnight and 2 A.M., although other time periods are possible. Preferably, the predetermined time period includes times when there is little to no sunlight. This will ensure that the only electricity entering the system will be from the utility, because the EG system (e.g., PV system) will not be able to generate enough power to overcome the load and push back into the grid. If the power data is not from the predetermined time period, then method 1000 ends or subsequently requests additional power measurement data. The power data can be received in real-time during the predetermined period. Alternatively, the power data can be received at any convenient time, as long as the power data represents power generated during the predetermined period. For example, power data can be collected at midnight, but method 1000 may request that data at a later time (e.g., noon).

At step 1030, the power measurement data is determined to be either a positive value or a negative value. A positive value is an indication that the net power flow is coming into the system (e.g., system 100) from the utility. This would be expected because a PV-based EG system would not generate any power (or any appreciable amount) during periods of little to no sunlight and any power to the load (e.g., loads 120, 122) would be provisioned by the utility, which would be associated with a net positive power flow into the system. Thus, a positive value for the power measurement data is a strong indicator that the power meter was installed correctly with the correct polarity.

A negative value would typically be an indication that the net power flow is being pushed out of the system. That is, the EG system (e.g., PV system 270) is generating enough power to satisfy load requirements (e.g., loads 120, 122) and push the remainder back onto the grid (e.g., utility grid 114). However, because the power data is collected during a period of time where no energy is generated by the EG system (e.g., periods of no sunlight), a negative value would be highly unlikely as no power would be pushed back onto the grid under these conditions. Thus, a negative value for the power measurement data during the predetermined time period is a strong indicator that the power meter was installed backwards with the wrong polarity. It should be noted that some embodiments may flip the negative and positive value convention such that a negative value indicates a net power coming into the system from the utility and a positive value indicates a net power pushing out of the system (e.g., due to PV over generation) and back into the utility grid.

At step 1050, if the power measurement data is determined to be negative during the predetermined time period, a negative coefficient is associated with the power measurement data. For instance, in some embodiments, after determining that the power meter was installed backwards, any power measurement data received from that particular power meter will be associated with a (−1) multiplier to permanently associate the correct polarity with the incorrectly installed power meter. In some embodiments, the negative data determination may or may not include a zero value. This software solution avoids the costly and time-intensive task of having a technician return to the site to manually reinstall the meter in the correct orientation.

At step 1040, if the power measurement data is determined to be positive during the predetermined time period, a positive coefficient may be associated with the power measurement data. For instance, in some embodiments, after determining that the power meter was installed correctly, any power measurement data received from that particular power meter will be associated with a (+1) multiplier, which effectively makes no change to the data. In alternative embodiments, no coefficient is associated with the power measurement data under these conditions. That is, when the power measurement data is determined to be positive during the predetermined time period, no change is made to the power measurement data going forward and the power measurement data is accepted as is. In some embodiments, the positive data determination may or may not include a zero value. In some cases, there may be a flag or other marker (stored locally and/or remotely) indicating that the particular power meter installation has been evaluated and no change to the polarity is required.

It should be appreciated that the specific steps illustrated in FIG. 10 provide a particular method 1000 of controlling power measurement data in a power grid, according to certain embodiments of the present invention. Other sequences of steps may also be performed according to alternative embodiments. For example, alternative embodiments of the present invention may perform the steps outlined above in a different order. Moreover, the individual steps illustrated in FIG. 10 may include multiple sub-steps that may be performed in various sequences as appropriate to the individual step. Furthermore, additional steps may be added or removed depending on the particular applications. For instance, the methods described herein (e.g., FIGS. 9 and 10) can be applied to single-phase or multi-phase systems (e.g., 2-phase, 3-phase, etc.). The various embodiments may apply to residential, commercial, or industrial EG systems, or combinations thereof. One of ordinary skill in the art would recognize and appreciate many variations, modifications, and alternatives of the method 1000.

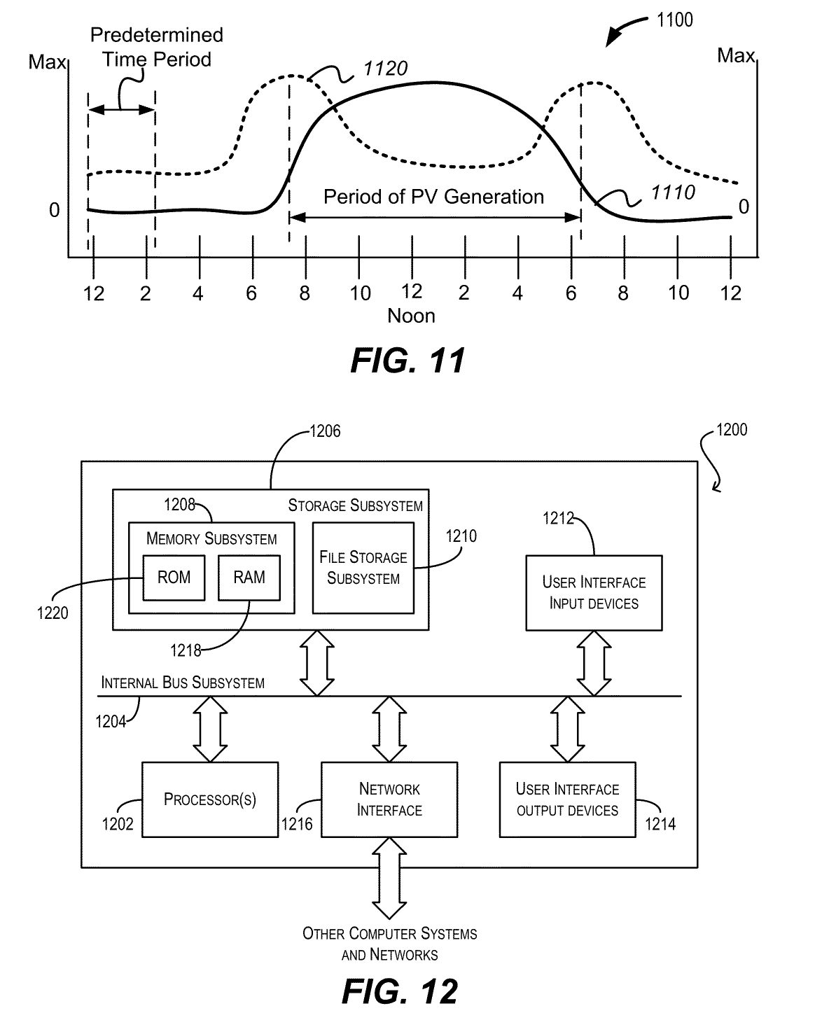

FIG. 11 shows a graph 1100 illustrating a typical predetermined time period for receiving power measurement data for one or more power meters in a PV-based energy generation system, according to certain embodiments of the invention. Graph 1100 depicts both PV-generation 1110 versus time (e.g., system 102) and a load requirement 1120 versus time (e.g., loads 120, 122) in a typical residential EG system, such as system 100 of FIG. 1. This example is non-limiting and other PV generation curves and load curves are possible.

PV generation curve 1110 generates little to no power during periods of no sunlight. In this example, sunrise occurs around 7:30 AM and sundown occurs around 7 PM. Maximum PV generation tends to occur during periods of maximal sunlight, which is typically between 10 AM and 2 PM. The amount of power generated by the PV system (e.g., system 102) depends on the size of the solar system and the amount of sunlight reaching the solar panels. Some typical solar systems may be 3-5 KW system, but other systems are possible and may depend on the size of the installation site (e.g., residential, commercial, industrial), as would be appreciated by one of ordinary skill in the art. For the purposes of illustration, the PV output is defined in terms of a zero value (or minimum value) and a maximum value, as shown in the y-axis marker on the left side of graph 1100. Furthermore, sunrise and sundown may occur at different times depending on geographic location, time of the year, etc. It should be understood that this example is intended to provide a simplified representation of a typical PV generation curve in a typical residential setting.

Load curve 1120 peaks around 7 AM and 7 PM, which is typical for many households. During the night, most people are sleeping and few appliances are typically running Thus, load curve 1120 shows low load requirements during this time. At around 7 AM and 7 PM, most people are either getting ready for school or work, or coming back. Air conditioning units, televisions, lights, kitchen appliances, and other loads are most likely being used during these times, as reflected in the load curve. The dip in load curve 1120 between about 8:30 AM and 5 PM is typical of most households as the occupants are typically at work or school. For the purposes of illustration, load curve 1120 is defined in terms of a zero value (or minimum value) and a maximum value. Furthermore, load characteristics over time may have peaks or troughs and/or minimum and maximum values at different times of the day. It should be understood that this example is intended to provide a simplified representation of a typical load curve in a typical residential setting.

As previously described, in order to remotely determine whether a power meter is installed with the correct polarity (proper orientation), power measurement data should be collected during periods of little to no PV generation. During these periods, it is expected that power entering the system and provisioning the load would be net positive, as the utility (e.g., electric company) would provide most of the power to the load because PV generation alone would not meet the load requirement, as shown in FIG. 11. In exemplary embodiments, the predetermined time period is typically chosen to be between 10 PM and 2 PM. Other times or periods are possible. For instance, the predetermined time period can be shorter (e.g., seconds, minutes, hours, etc.). Also, the predetermined time periods may occur during a different range of time, such as between midnight and 1 AM. Those of ordinary skill in the art would appreciate an appropriate predetermined time period based on geographic location, climate, typical sunrise/sunset, etc., to ensure that little to no PV generation is occurring when requesting power measurement data for determining power meter orientation, as discussed above.

### System Architectures

FIG. 12 shows a simplified block diagram of a computer system 1200 according to an embodiment of the present invention. Computer system 1200 can be used to implement any of the computer systems/devices (e.g., site gateway 124, control server 128) described with respect to FIG. 1. As shown in FIG. 12, computer system 1200 can include one or more processors 1202 that communicate with a number of peripheral devices via a bus subsystem 1204. These peripheral devices can include a storage subsystem 1206 (comprising a memory subsystem 1208 and a file storage subsystem 1210), user interface input devices 1212, user interface output devices 1214, and a network interface subsystem 1216.

Internal bus subsystem 1204 can provide a mechanism for letting the various components and subsystems of computer system 1200 communicate with each other. Although internal bus subsystem 1204 is shown schematically as a single bus, alternative embodiments of the bus subsystem can utilize multiple buses.

Network interface subsystem 1216 can serve as an interface for communicating data between computer system 1200 and other computer systems or networks (e.g., network 126 of FIG. 1). Embodiments of network interface subsystem 1216 can include wired interfaces (e.g., Ethernet, CAN, RS232, RS485, etc.) or wireless interfaces (e.g., ZigBee, Wi-Fi, cellular, etc.).

User interface input devices 1212 can include a keyboard, pointing devices (e.g., mouse, trackball, touchpad, etc.), a scanner, a barcode scanner, a touch-screen incorporated into a display, audio input devices (e.g., voice recognition systems, microphones, etc.), and other types of input devices. In general, use of the term “input device” is intended to include all possible types of devices and mechanisms for inputting information into computer system 1200.

User interface output devices 1214 can include a display subsystem, a printer, a fax machine, or non-visual displays such as audio output devices, etc. The display subsystem can be a cathode ray tube (CRT), a flat-panel device such as a liquid crystal display (LCD), or a projection device. In general, use of the term “output device” is intended to include all possible types of devices and mechanisms for outputting information from computer system 1200.

Storage subsystem 1206 can include a memory subsystem 1208 and a file/disk storage subsystem 1210. Subsystems 1208 and 1210 represent non-transitory computer-readable storage media that can store program code and/or data that provide the functionality of embodiments of the present invention.

Memory subsystem 1208 can include a number of memories including a main random access memory (RAM) 1218 for storage of instructions and data during program execution and a read-only memory (ROM) 1220 in which fixed instructions are stored. File storage subsystem 1210 can provide persistent (i.e., non-volatile) storage for program and data files, and can include a magnetic or solid-state hard disk drive, an optical drive along with associated removable media (e.g., CD-ROM, DVD, Blu-Ray, etc.), a removable flash memory-based drive or card, and/or other types of storage media known in the art.

It should be appreciated that computer system 1200 is illustrative and not intended to limit embodiments of the present invention. Many other configurations having more or fewer components than system 1200 are possible.

The above description illustrates various embodiments of the present invention along with examples of how aspects of the present invention may be implemented. The above examples and embodiments should not be deemed to be the only embodiments, and are presented to illustrate the flexibility and advantages of the present invention as defined by the following claims. For example, although certain embodiments have been described with respect to particular process flows and steps, it should be apparent to those skilled in the art that the scope of the present invention is not strictly limited to the described flows and steps. Steps described as sequential may be executed in parallel, order of steps may be varied, and steps may be modified, combined, added, or omitted. As another example, although certain embodiments have been described using a particular combination of hardware and software, it should be recognized that other combinations of hardware and software are possible, and that specific operations described as being implemented in software can also be implemented in hardware and vice versa.

The specification and drawings are, accordingly, to be regarded in an illustrative rather than restrictive sense. Other arrangements, embodiments, implementations and equivalents will be evident to those skilled in the art and may be employed without departing from the spirit and scope of the invention as set forth in the following claims.

What is claimed is:

1. A computer-implemented method for measuring power at an energy-generation (EG) site, the method comprising:
requesting, by a processor, power measurement data from a power meter during a predetermined time period,
wherein the power meter is configured to measure power usage from the EG site including power provided by:
an electrical utility grid; and
an EG system at the EG site;
receiving, by the processor from the power meter, the power measurement data;
associating, by the processor, a coefficient with the power measurement data based on the direction of the net power flow from the EG site; and
calculating, by the processor, a power measurement for the energy generation site based, in part, on the associated coefficient.

2. The computer-implemented method of claim 1 further comprising:
associating, by the processor, a negative coefficient with the power measurement data when the power measurement is less than zero; and
associating, by the processor, a positive coefficient with the power measurement data when the power measurement is equal to or greater than zero.

3. The computer-implemented method of claim 2, wherein the power measurement data includes:
a first power measurement corresponding to a first phase of power; and
a second power measurement corresponding to a second phase of power, wherein the second power measurement is received from a second power meter at the EG site,
wherein associating the negative coefficient or the positive coefficient with the power measurement data applies to the first phase of power; and
the method further comprises associating a second negative or positive coefficient with the second power measurement corresponding to the second phase of power.

4. The computer-implemented method of claim 3 wherein the power measurement data further includes a third power measurement corresponding to a third phase of power, wherein the third power measurement is received from a third power meter at the EG site; and
the method further comprises associating a third negative or positive coefficient with the third power measurement corresponding to the third phase of power.

5. The computer-implemented method of claim 1 wherein the predetermined time period occurs during a period when the EG system generates its lowest power levels.

6. The computer-implemented method of claim 1 wherein the predetermined time period occurs during a period of substantially no sunlight if the EG system includes photo-voltaic power.

7. The computer-implemented method of claim 1 wherein the power meter is a current transducer.

8. The computer-implemented method of claim 3 wherein each of the first and second power measurements are measured by separate transducers.

9. The computer-implemented method of claim 4 wherein each of the first, second, and third power measurements are measured by different transducers.

10. A system comprising:
one or more processors; and
one or more non-transitory computer-readable storage mediums containing instructions configured to cause the one or more processors to perform operations including:
generating a request, by the one or more processors, to receive power measurement data from a power meter at an energy-generation (EG) site during a predetermined time period, wherein the power meter is configured to measure power usage from the EG site including power provided by:
an electrical utility grid; and
an EG system at the EG site;
sending the request, by the one or more processors, to the power meter;
receiving, by the one or more processors from the power meter, the power measurement data;
associating, by the one or more processors, one or more coefficients with the power measurement data based on the direction of the net power flow from the EG site, wherein the associating is performed on subsequent power measurement data received from the power meter, and wherein the association of the one or more coefficients with the power meter are stored in a database; and
calculating, by the one or more processors, a power measurement for the energy generation site based, in part, on the associated coefficient.

11. The system of claim 10, wherein the one or more computer-readable storage mediums further comprise instructions configured to cause the one or more processors to perform operations including:
associating, by the one or more processors, a negative coefficient with the power measurement data when the power measurement is less than zero; and
associating, by the one or more processors, a positive coefficient with the power measurement data when the power measurement is equal to or greater than zero.

12. The system of claim 10 wherein the power measurement data includes:
a first power measurement corresponding to a first phase of power; and
a second power measurement corresponding to a second phase of power,
wherein associating the negative coefficient or the positive coefficient with the power measurement data applies to both the first and second phases of power.

13. The system of claim 10 wherein the power measurement data includes:
a first power measurement corresponding to a first phase of power;
a second power measurement corresponding to a second phase of power, and
a third power measurement corresponding to a second phase of power,
wherein associating the negative coefficient or the positive coefficient with the power measurement data applies to each measured phase of power.

14. The system of claim 10 wherein the predetermined time period occurs during a period when the EG system generates its lowest power levels.

15. The system of claim 10 wherein the predetermined time period occurs during a period of time of historically lowest levels of PV-based energy generation.

16. The system of claim 10 wherein the power meter comprises a transducer.

17. The system of claim 12 wherein each of the first and second power measurements are measured by different power meters, and wherein each power meter comprises a current transducer.

18. The system of claim 13 wherein each of the first, second, and third power measurements are measured by separate power meters, and wherein each power meter comprises a current transducer.

19. A computer-implemented method for measuring power at an energy-generation (EG) site, the method comprising:
requesting, by a processor, power measurement data from a power meter during a predetermined time period, wherein the power meter is configured to measure power usage from the EG site including power provided by:
an electrical utility grid; and
an EG system at the EG site;
receiving, by the processor from the power meter, the power measurement data;
associating power provided by the electrical utility grid with a first coefficient having a first polarity;
associating power provided by the EG system with a second coefficient having a second polarity different from the first polarity;
determining whether a net power flow from the electrical utility grid and the EG system is of the first polarity or the second polarity; and
calculating a power measurement for the power generation site based, in part, on the polarity of the net power flow.

20. The computer-implemented method of claim 19 wherein the predetermined time period occurs during a period when the EG system generates its lowest daily power levels.
